(19) United States
(12) Patent Application Publication
(10) Pub. No.: US 2023/0299782 A1
(43) Pub. Date: Sep. 21, 2023

(54) INTEGRATED CIRCUIT

(71) Applicants: Kabushiki Kaisha Toshiba, Tokyo (JP); Toshiba Electronic Devices & Storage Corporation, Tokyo (JP)

(72) Inventor: Yoshimitsu SHIMOJO, Kawasaki Kanagawa (JP)

(21) Appl. No.: 17/892,980

(22) Filed: Aug. 22, 2022

(30) Foreign Application Priority Data
Mar. 17, 2022 (JP) 2022-043064

(51) Int. Cl. H03M 1/06

(52) U.S. Cl. CPC H03M 1/0697

(57) ABSTRACT

An integrated circuit of an embodiment includes a plurality of AD conversion circuits including a first AD conversion circuit and a second AD conversion circuit, and a control circuit configured to delay a start time of sampling processing of the second AD conversion circuit as compared with a usual start time such that the first AD conversion circuit is not influenced by noise generated by the sampling processing of the second AD conversion circuit, and to shorten a sampling time period to control a termination time of the sampling processing of the second AD conversion circuit to be concurrent with a termination time in a case of performing usual sampling processing.

### CROSS-REFERENCE TO RELATED APPLICATIONS

This application is based upon and claims the benefit of priority from the prior Japanese Patent Application No. 2022-43064 filed on Mar. 17, 2022; the entire contents of which are incorporated herein by reference.

### FIELD

Embodiments described herein relate generally to an integrated circuit having a plurality of AD conversion circuits.

### BACKGROUND

Processing of an AD conversion circuit can be divided into two kinds of processing: sampling processing and conversion processing. In the sampling processing, charging of a capacitor with an inputted analog signal is started when a conversion trigger is received, and the analog signal is held in the capacitor when a predetermined sampling time period elapses. In the conversion processing, the held inputted signal is converted into a digital value by a method such as sequential comparison.

### BRIEF DESCRIPTION OF THE DRAWINGS

FIG. 1 is a configuration diagram of an integrated circuit of an embodiment;

FIG. 2 is a diagram showing periods in which noise is generated in an AD conversion circuit and periods in which the AD conversion circuit is likely to be influenced by noise;

FIG. 3 is a diagram describing operation of a plurality of AD conversion circuits of a conventional integrated circuit;

FIG. 4 is a diagram describing operation of a plurality of AD conversion circuits of an integrated circuit of a first embodiment;

FIG. 5 is a diagram showing a change in amount of charge in a capacitor of an AD conversion circuit;

FIG. 6 is a diagram describing operation of the AD conversion circuit of the integrated circuit of the first embodiment;

FIG. 7 is a diagram describing operation of AD conversion circuits of an integrated circuit of a second embodiment;

FIG. 8 is a diagram showing a change in amount of charge in a capacitor of an AD conversion circuit;

FIG. 9 is a diagram describing operation of the AD conversion circuit of the integrated circuit of the second embodiment; and

FIG. 10 is a diagram describing operation of a plurality of AD conversion circuits of an integrated circuit of a third embodiment.

### DETAILED DESCRIPTION

An integrated circuit of an embodiment includes a plurality of AD conversion circuits including a first AD conversion circuit and a second AD conversion circuit, and a control circuit configured to delay a start time of sampling processing of the second AD conversion circuit as compared with a usual start time such that the first AD conversion circuit is not influenced by noise generated by the sampling processing of the second AD conversion circuit, and to shorten a sampling time period to control a termination time of the sampling processing of the second AD conversion circuit to be concurrent with a termination time in a case of performing usual sampling processing.

### First Embodiment

Hereinafter, an integrated circuit 1 of a first embodiment will be described in detail with reference to the drawings.

The drawings based on embodiments are schematic, and relative time displays of each processing are different from actual time displays.

An AD conversion circuit may generate large noise in an initial period of sampling processing (hereinafter, a start period of the sampling processing) and in an initial period of conversion processing (hereinafter, a start period of the conversion processing). The AD conversion circuit is most likely to be influenced by noise in a final period of the sampling processing (hereinafter, a termination period of the sampling processing) and in a final period of the processing of conversion into a digital signal (hereinafter, a termination period of the conversion processing).

In an integrated circuit having a plurality of: D conversion circuits, a first AD conversion circuit may be influenced by noise generated by a second AD conversion circuit when the second AD conversion circuit starts sampling in the termination period of the sampling processing of the first AD conversion circuit, for example, and may deteriorate in accuracy of AD conversion of the first AD conversion circuit.

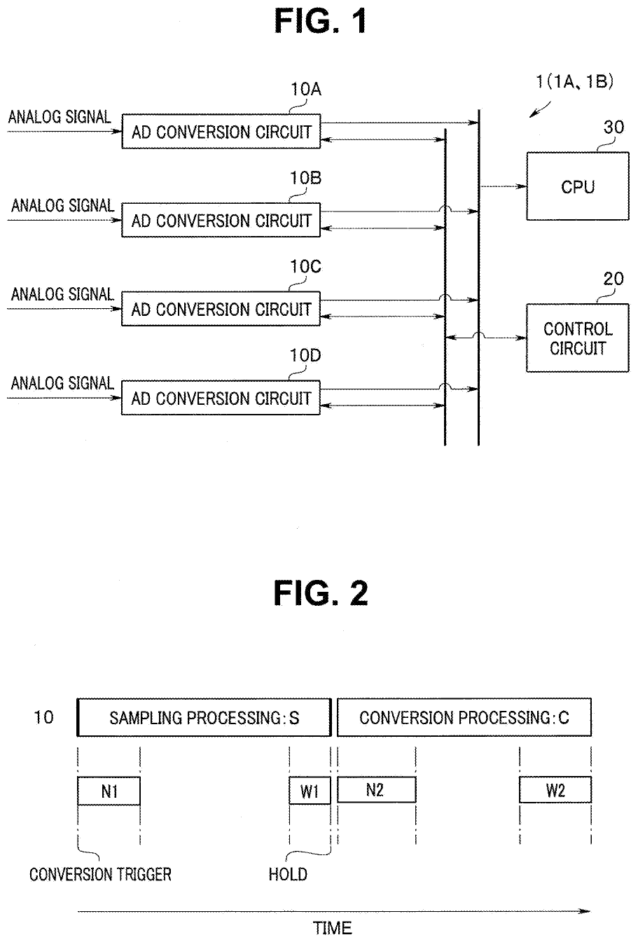

As shown in FIG. 1, the integrated circuit 1 of the embodiment includes a plurality of AD conversion circuits (conversion channels) 10A to 10D including a first AD conversion circuit 10A and a second AD conversion circuit 10B, a CPU 30, and a control circuit (control unit) 20. The control circuit 20 may be part of the CPU 30. The integrated circuit 1 is a microcomputer, for example. The control circuit 20 controls operation of the AD conversion circuits 10A to 10D. Hereinafter, each of the plurality of AD conversion circuits 10A to 10D will be referred to as an AD conversion circuit 10. The number of AD conversion circuits 10 is more than or equal to 2 and less than or equal to 64, for example.

As shown in FIG. 2, when a conversion trigger is received, the AD conversion circuit 10 starts sampling processing S (analog processing) of an analog signal, that is, charging of a capacitor of the integrated circuit. As already described, large noise may be generated in a first period N1 which is a start period of the sampling processing S by switch opening operation when connecting an input line of the analog signal to the capacitor. The noise gradually decreases to a negligible level when the first period N1 elapses. The first period N1 is a period of more than or equal to 10% and less than or equal to 30% of a time period of the sampling processing S, for example.

When the AD conversion circuit 10 is influenced by noise in a second period. W1 which is the termination period of the sampling processing S in which charges are accumulated in the capacitor, the inputted analog signal cannot be accurately reflected in the amount of charge accumulated in the capacitor. This may eventually lead to significantly deteriorated conversion accuracy. The second period W1 is a period of more than or equal to 10% and less than or equal to 30% of the time period of the sampling processing S, for example.

In other words, the AD conversion circuit 10 is likely to generate noise in the first period N1 which is the start period of the sampling processing S, and is likely to be influenced by noise in the second period W1 which is the termination period of the sampling processing S.

In the AD conversion circuit 10, large noise may be generated by operation of determining a high-order bit in sequential conversion processing in a third period N2 which is a start period of conversion processing C (digital processing). Noise gradually decreases to a negligible level when the third period N2 elapses. The third period N2 is a period of more than or equal to 10% and less than or equal to 30% of a time period of the conversion processing C, for example.

When the AD conversion circuit 10 is influenced by noise in a fourth period. W2 which is a termination period of the conversion processing C, the AD conversion circuit 10 cannot accurately determine a low-order bit in the sequential conversion processing. This may eventually lead to significantly deteriorated conversion accuracy. The fourth period W2 is a period of more than or equal to 10% and less than or equal to 30% of the time period of the conversion processing C, for example.

In other words, the AD conversion circuit 10 is likely to generate noise in the third period N2 which is the start period of the conversion processing C, and is likely to be influenced by noise in the fourth period W2 which is the termination period of the conversion processing C.

However, in the integrated circuit 1 of the present embodiment which will be described below, an influence of noise generated by the sampling processing S is remarkable, and an influence of noise generated by the conversion processing C is negligible.

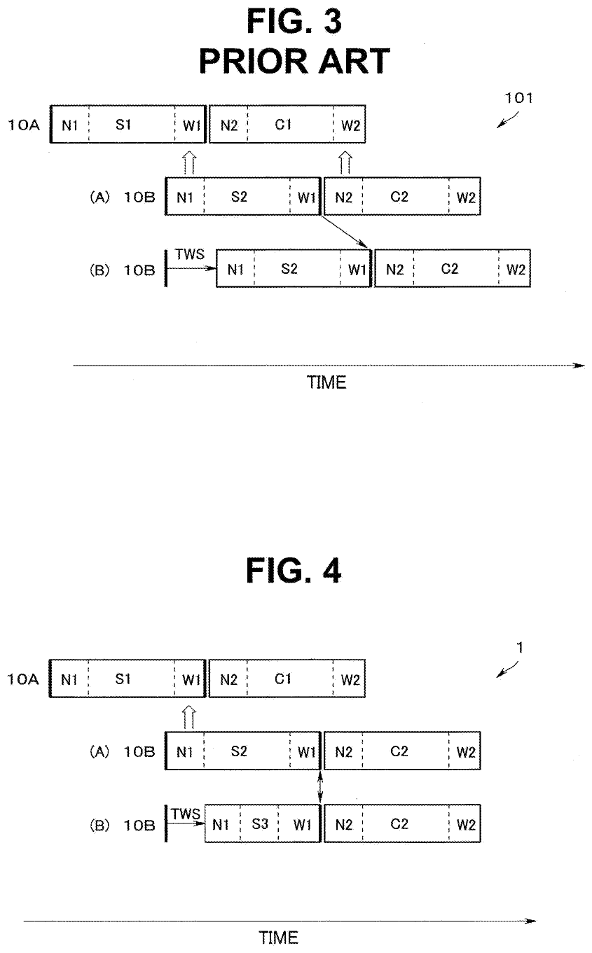

As shown in FIG. 3(A), when the second AD conversion circuit 10B starts the sampling processing S2 in the termination period W1 of the sampling processing S1 of the first AD conversion circuit 10A, the first AD conversion circuit 10A may be influenced by noise generated by the second AD conversion circuit 10B in the start period N1, which leads to deteriorated conversion accuracy.

In a conventional integrated circuit 101 shown in FIG. 3(B), the control circuit 20 delays start of the sampling processing S2 of the second AD conversion circuit 10B by a sampling start waiting time period TWS (hereinafter referred to as an “S waiting time period TWS”) in order to prevent deterioration in conversion accuracy. The S waiting time period TWS is more than or equal to a time period by which the sampling processing S2 of the second. AD conversion circuit 10B is started after the second period W1 of the first AD conversion circuit 10A is terminated.

However, since the above-described conventional control method (B) delays the start of the sampling processing S2 of the second AD conversion circuit 10B, the termination of the sampling processing S2, that is, a time for holding an inputted signal, is delayed as compared with a usual time.

For example, in an integrated circuit that continually digitizes a time-varying analog signal in a constant cycle, a temporal variation of the time for holding an inputted signal is another major cause of reduction in accuracy.

In the integrated circuit 1 of the present embodiment shown in FIG. 4, in a case in which (A) the sampling start period N1 of the second AD conversion circuit 10B overlaps the sampling termination period W1 of the first AD conversion circuit 10A, the control circuit 20 exerts control to not only delay (B) the start of the sampling processing S3 of the second AD conversion circuit 10B by the S waiting time period TWS, but also shorten the time period of the sampling processing S3 by the S waiting time period TWS such that the time for holding an inputted signal is concurrent with a usual time.

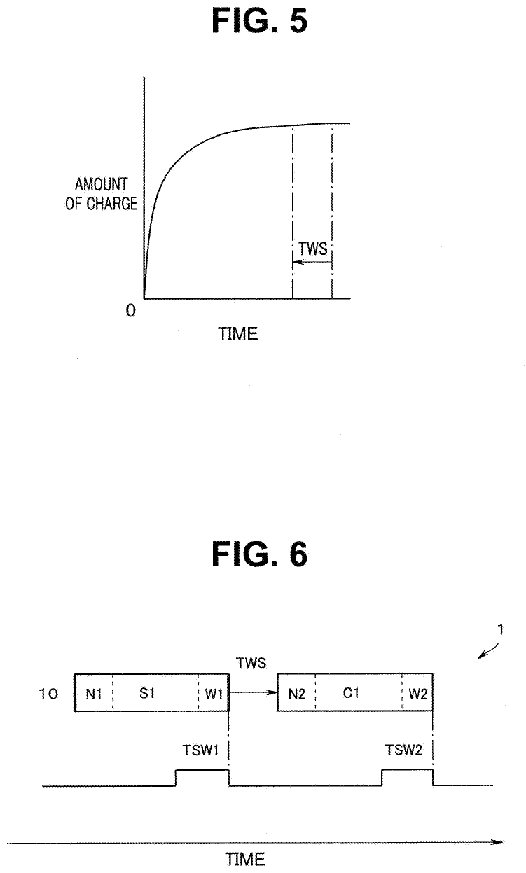

As shown in FIG. 5, the amount of charge in the capacitor abruptly rises in an initial period of sampling, whereas there is little change in the sampling termination period. Thus, the AD conversion accuracy is not significantly reduced even if the sampling time period is shortened.

Note that when the sampling time period is excessively shortened, the accuracy of AD conversion is reduced. Therefore, the minimum value of the sampling processing time period (the maximum value of the S waiting time period TWS) is determined within a range in which requirements for accuracy of AD conversion are satisfied.

As described above, in the integrated circuit 1 of the present embodiment, the control circuit 20 exerts control to delay the start time of the sampling processing S2 of the second AD conversion circuit 10B by the S waiting time period TWS as compared with a usual start time such that the first AD conversion circuit 10A is not influenced by noise generated by the sampling processing S2 of the second AD conversion circuit 10B, but to shorten the sampling time period such that the termination time of the sampling processing of the second AD conversion circuit 10B is concurrent with a termination time in a case of performing usual sampling processing.

As shown in FIG. 6, when a certain AD conversion circuit 10 starts the sampling processing, the control circuit 20 sets sampling processing start prohibited periods (hereinafter referred to as “S prohibited periods”) TSW1 and TSW2 such that another AD conversion circuit is not influenced by noise generated in the sampling processing. All the AD conversion circuits except the AD conversion circuit 10 wait for the S waiting time period TWS without starting the sampling processing in the S prohibited periods TSW1 and TSW2 even if a conversion trigger is received.

The S prohibited period TSW1 corresponds to the second period W1 which is the termination period of the sampling processing S. The S prohibited period TSW2 corresponds to the fourth period W2 which is the termination period of the conversion processing C.

The S prohibited period TSW1 is terminated at a time when the sampling processing is terminated (when data is held), and is determined by a total time period of the first period N1 and the second period W1, for example.

The S prohibited period TSW2 is terminated at a time when the conversion processing is terminated, and is a total time period of the third period N2 and the fourth period W2, for example. The lengths of the S prohibited periods TSW1 and TSW2 are set in a control register so as to be changed in accordance with a use environment of the integrated circuit, on the basis of the total time period of the third period N2 and the fourth period W2.

Since the integrated circuit 1 is not influenced by noise generated by the sampling processing 5, high conversion accuracy can be achieved. The integrated circuit 1 can also achieve high conversion accuracy particularly in a case of continually digitizing a time-varying analog signal in a constant cycle.

### Second Embodiment

Since an integrated circuit 1A of a second embodiment is similar to the integrated circuit 1 and has the same effects, constitutional elements having the same functions are denoted the same reference characters, and their description is omitted. In the integrated circuit 1A, an influence of noise generated by the conversion processing C is remarkable, and an influence of noise generated by the sampling processing S is negligible.

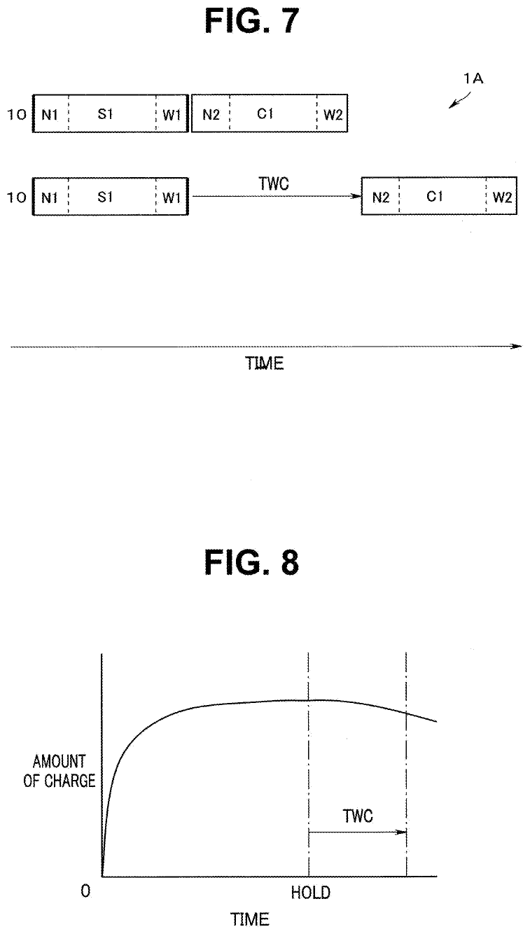

As shown in FIG. 7, in the integrated circuit 1A, the control circuit 20 exerts control to delay a start time of the conversion processing C of the AD conversion circuit 10 by a conversion processing start waiting time period TWC (hereinafter referred to as a “C waiting time period TWC”) as compared with a usual time such that noise generated by the conversion processing C of the AD conversion circuit 10 does not influence another AD conversion circuit. All the AD conversion circuits except the AD conversion circuit 10 which has started the conversion processing wait for the C waiting time period TWC without starting the conversion processing in C prohibited periods TCW1 and TCW2 even if data holding is completed.

As shown in FIG. 8, since the amount of charge in the capacitor of the AD conversion circuit 10 gradually decreases after holding because of a cause such as leakage, the AD conversion accuracy deteriorates. The C waiting time period TWC is determined within a range in which requirements for the AD conversion accuracy are satisfied.

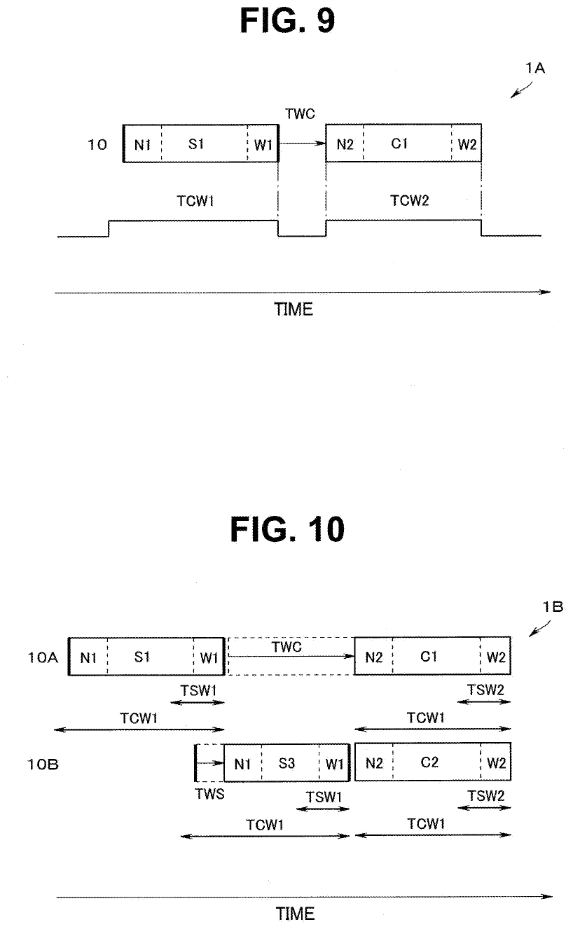

As shown in FIG. 9, the control circuit 20 sets conversion processing start prohibited periods (hereinafter referred to as “C prohibited periods”) TCW1 and TCW2 such that a certain AD conversion circuit 10 is not influenced by noise generated by another AD conversion circuit in the conversion processing.

The C prohibited period TCW1 corresponds to the second period W1 which is the termination period of the sampling processing S. The C prohibited period TCW2 corresponds to the fourth period W2 which is the termination period of the conversion processing C.

The C prohibited period TCW1 is terminated at a time when the sampling processing is terminated (when data is held), and is a total time period of the second period W1 and the sampling processing time period, for example. The C prohibited period TCW2 is terminated at a time when the conversion processing is terminated, and is a conversion processing time period, for example.

As for lengths of the C prohibited periods TCW1 and TCW2, values set in the control register can be changed in accordance with a use environment of the integrated circuit on the basis of the above-described time periods.

Since the integrated circuit 1A is not influenced by noise generated by the conversion processing, high conversion accuracy can be achieved.

### Third Embodiment

Since an integrated circuit 1B of a third embodiment is similar to the integrated circuits 1 and 1A, and has the same effects, constitutional elements having the same functions are denoted the same reference characters, and their description is omitted. In the integrated circuit 1B, the control circuit 20 exerts control taking an influence of noise generated by the conversion processing and an influence of noise generated by the sampling processing into consideration.

As shown in FIG. 10, in the integrated circuit 1B, when a conversion trigger for starting the sampling processing S1 of the first AD conversion circuit 10A is produced, the control circuit 20 determines whether the first AD conversion circuit 10A can start the sampling processing S1. Specifically, the control circuit 20 determines whether the start period N1 of the sampling processing S1 overlaps the S prohibited periods TSW1 and TSW2 of another AD conversion circuit (the second AD conversion circuit 10B).

In the example shown in FIG. 10, the start period N1 of the sampling processing S1 of the first AD conversion circuit 10A does not overlap the S prohibited periods TSW1 and TSW2. Thus, the first AD conversion circuit 10A starts the sampling processing without an S waiting time period.

Next, a conversion trigger of the second AD conversion circuit 10B is produced. The control circuit 20 determines whether the second AD conversion circuit 10B can start the sampling processing S3. Specifically, the control circuit 20 determines whether the start period (N1) of the sampling processing S3 of the second AD conversion circuit 10B temporally overlaps the S prohibited periods TSW1 and TSW2 of another AD conversion circuit (the first AD conversion circuit 10A).

In FIG. 10, the start period N1 of the sampling processing S3 of the second AD conversion circuit 10B overlaps the S prohibited period TSW1 of the first AD conversion circuit 10A. Thus, the control circuit 20 suspends the start of the sampling processing S3 of the second AD conversion circuit 10B for the 5 waiting time period TWS until the S prohibited period TSW1 of the first AD conversion circuit 10A elapses. In this manner, the control circuit 20 delays the start of the sampling processing of the second AD conversion circuit 10B until a state in which the start period N1 of the second AD conversion circuit 10B does not overlap TSW1 and TSW2 of another AD conversion circuit is brought about, and starts the sampling processing of the second AD conversion circuit 10B.

Further, the control circuit 20 controls the time period of the sampling processing S3 of the second AD conversion circuit 10B to be shortened such that the termination time of the sampling processing S3 (the time for holding an inputted signal) does not change.

After the sampling processing S1 of the first AD conversion circuit 10A is terminated, the control circuit 20 determines whether the first AD conversion circuit 10A can start the conversion processing C1. Specifically, the control circuit 20 determines whether the C start period N2 of the first AD conversion circuit 10A overlaps the C prohibited periods TCW1 and TCW2 of another channel (the second AD conversion circuit 10B). In FIG. 10, the C start period N2 of the first AD conversion circuit 10A overlaps the C prohibited period TCW1 of the second AD conversion circuit 10B. Thus, the control circuit 20 exerts control to delay the start of the conversion processing of the first AD conversion circuit 10A for the C waiting time period TWC until after the C prohibited period TCW1 is terminated and until before the C prohibited period TCW2 is started. In this manner, the first AD conversion circuit 10A delays the start of the conversion processing to a time overlapping neither the C prohibited period TCW1 nor TCW2 of another AD conversion circuit, and, then starts the conversion processing.

After the sampling processing S3 of the second AD conversion circuit 10B is terminated, the control circuit 20 determines whether the second AD conversion circuit 10B can start the conversion processing C2. Specifically, the control circuit 20 confirms if the conversion processing start period N2 of the second AD conversion circuit 10B overlaps the C prohibited periods TCW1 and TCW2 of another AD conversion circuit (the first AD conversion circuit 10A). In FIG. 10, since the conversion processing start, period N2 of the second AD conversion circuit 10B does not overlap the C prohibited periods TCW1 and TCW2 of the other AD conversion circuit, the second AD conversion circuit 10B immediately starts the conversion processing C2.

As described above, the integrated circuit 1B of the present embodiment can avoid overlapping of a period in which an AD conversion circuit is likely to generate noise and a period in which another AD conversion circuit is likely to be influenced by noise without changing a time period from when a conversion trigger is inputted until when an inputted signal is held (the sampling processing is completed). Thus, the integrated circuit 1B can prevent a conversion result from deteriorating in accuracy. The integrated circuit 1B can also achieve high conversion accuracy particularly in a case of continually digitizing a time-varying analog signal in a constant cycle.

Specifically, each of the AD conversion circuits 10 outputs a data signal of the S prohibited periods TSW1, TSW2 and the C prohibited periods TCW1, TCW2. An integration block of the control circuit 20 calculates a logical sum of each of the S prohibited periods TSW1, TSW2 and the C prohibited periods TCW1, TCW2 of the plurality of AD conversion circuits 10, generates signals of an integrated S prohibited period and an integrated C prohibited period, and transmits the generated signals to each of the AD conversion circuits 10 as control signals.

Note that, for example, each of the AD conversion circuits 10 may calculate the logical sum of the S prohibited periods TSW1, TSW2 and the logical sum of the C prohibited periods TCW1, TCW2 and output the logical sums to the control circuit 20, and the integration block of the control circuit 20 may perform integration of the S prohibited periods and the C prohibited periods of the plurality of AD conversion circuits 10. Alternatively, each of the AD conversion circuits 10 may output the start time of the sampling processing and the start time of the conversion processing, and the control circuit 20 may generate signals indicating the S prohibited periods and the C prohibited periods in the integration block, and integrate the S prohibited periods and the C prohibited periods.

In a case in which a large number of the AD conversion circuits 10 operate at the same time, a case is considered in which it is impossible to avoid overlapping of the first period N1, the third period N2 and the second period W1, the fourth period W2 even if the S waiting time period and the C waiting time period are adjusted.

In such a case, for example, the S prohibited periods and the C prohibited periods set in the control register are changed to be shorter than the S prohibited periods and the C prohibited periods in usual processing. Alternatively, the lengths of the first period N1, the second period W1, the third period N2, and the fourth period W2 may be changed to be shorter than the lengths of the first period N1, the second period W1, the third period N2, and the fourth period W2 in usual processing.

For example, the control circuit 20 may set the start period (the first period N1) of the sampling processing at a period less than 10% of the time period of usual sampling processing. The lengths of the first period N1, the second period W1, the third period N2, and the fourth period W2 may be set in accordance with specifications of the AD conversion accuracy. For example, when the first period N1 and the like are made longer, the conversion accuracy is improved, and when the first period N1 and the like are made shorter, the conversion accuracy is reduced.

The control circuit 20 may also designate an AD conversion circuit in which reduction in accuracy is permitted and an important AD conversion circuit in which reduction in accuracy is not, permitted to preferentially ensure the accuracy of the important AD conversion circuit. For example, the accuracy of the important AD conversion circuit can easily be maintained if output of the AD conversion circuit in which reduction in accuracy is permitted in the S prohibited periods and the C prohibited periods is set at zero.

Note that the plurality of AD conversion circuits 10 and the control circuit 20 may each be an independent dedicated circuit, or may be implemented by a processor reading and executing a program and various types of information stored in a memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An integrated circuit comprising:
a plurality of AD conversion circuits including a first AD conversion circuit and a second AD conversion circuit; and
a control circuit configured to delay a start time of sampling processing of the second AD conversion circuit by a sampling processing start waiting time period as compared with a usual start time such that the first AD conversion circuit is not influenced by noise generated by the sampling processing of the second AD conversion circuit, and to shorten a sampling time period to control a termination time of the sampling processing of the second AD conversion circuit to be concurrent with a termination time in a case of performing usual sampling processing.

2. The integrated circuit according to claim 1, wherein the control circuit controls a termination period of sampling processing and a termination period of conversion processing of the first AD conversion circuit not to overlap a start period of the sampling processing of the second AD conversion circuit.

3. The integrated circuit according to claim 2, wherein the sampling processing start waiting time period, the start period of the sampling processing, the termination period of the sampling processing, and the termination period of the conversion processing are set in accordance with a specification of AD conversion accuracy.

4. The integrated circuit according to claim 3, wherein the control circuit designates a plurality of AD conversion circuits in which reduction in accuracy is permitted and a plurality of important AD conversion circuits in which reduction in accuracy is not permitted among the plurality of AD conversion circuits to preferentially ensure accuracy of the important AD conversion circuits.

5. An integrated circuit comprising:
a plurality of AD conversion circuits including a first AD conversion circuit and a second AD conversion circuit; and
a control circuit configured to exert control to delay a start time of conversion processing of the second AD conversion circuit by a conversion processing start waiting time period as compared with a usual time such that the first AD conversion circuit is not influenced by noise generated by the conversion processing of the second AD conversion circuit.

6. The integrated circuit according to claim 5, wherein the control circuit exerts control such that a termination period of sampling processing and a termination period of conversion processing of the first AD conversion circuit do not overlap a start period of the conversion processing of the second AD conversion circuit.

7. The integrated circuit according to claim 6, wherein the sampling processing start waiting time period, the conversion processing start waiting time period, the termination period of the sampling processing, the start period of the conversion processing, and the termination period of the conversion processing are set in accordance with a specification of AD conversion accuracy.

8. The integrated circuit according to claim 7, wherein the control circuit designates a plurality of AD conversion circuits in which reduction in accuracy is permitted and a plurality of important AD conversion circuits in which reduction in accuracy is not permitted among the plurality of AD conversion circuits to preferentially ensure accuracy of the important AD conversion circuits.

9. An integrated circuit comprising:
a plurality of AD conversion circuits including a first AD conversion circuit and a second AD conversion circuit; and
a control circuit configured to
delay a start time of sampling processing of the second AD conversion circuit by a sampling processing start waiting time period as compared with a usual start time such that the first AD conversion circuit is not influenced by noise generated by the sampling processing of the second AD conversion circuit, and to shorten a sampling time period to control a termination time of the sampling processing of the second AD conversion circuit to be concurrent with a termination time in a case of performing usual sampling processing, and
exert control to delay a start time of conversion processing of the second AD conversion circuit by a conversion processing start waiting time period as compared with a usual time such that the first AD conversion circuit is not influenced by noise generated by the conversion processing of the second AD conversion circuit.

10. The integrated circuit according to claim 9, wherein the control circuit exerts control such that a termination period of sampling processing and a start period of conversion processing of the first AD conversion circuit do not overlap a start period of the sampling processing and a termination period of the conversion processing of the second AD conversion circuit.

11. The integrated circuit according to claim 10, wherein the sampling processing start waiting time period, the conversion processing start waiting time period, the start period of the sampling processing, the termination period of the sampling processing, the start period of the conversion processing, and the termination period of the conversion processing are set in accordance with a specification of AD conversion accuracy.

12. The integrated circuit according to claim 11, wherein the control circuit designates a plurality of AD conversion circuits in which reduction in accuracy is permitted and a plurality of important AD conversion circuits in which reduction in accuracy is not permitted among the plurality of AD conversion circuits to preferentially ensure accuracy of the important AD conversion circuits.
